(19) United States
(12) Patent Application Publication
(10) Pub. No.: US 2016/0376705 A1
(43) Pub. Date: Dec. 29, 2016

(54) Method for optical coating of large scale substrates

(71) Applicant: The Regents of the University of California, Oakland, CA (US)

(72) Inventors: Andrew C. Phillips, Seiad Valley, CA (US); Nobuhiko Kobayashi, Sunnyvale, CA (US)

(21) Appl. No.: 15/180,959

(22) Filed: Jun. 13, 2016

Related U.S. Application Data
(60) Provisional application No. 62/184,696, filed on Jun. 25, 2015.

(51) Int. Cl. C23C 16/455

(52) U.S. Cl. CPC C23C 16/45525

(57) ABSTRACT

A large substrate is optically coated in a reaction chamber that is formed by joining the substrate and a plate using a compliant seal, where the substrate forms one wall of the reaction chamber and the plate forms an opposite wall of the reaction chamber. The shape of the inside surface of the plate matches that of the inside surface of the substrate and they are spaced close together to minimize the volume of the reaction chamber. Atomic layer deposition is used to deposit one or more optical thin film layers to produce a coating on only the inside surface of the substrate. The outside surface is not coated.

### CROSS-REFERENCE TO RELATED APPLICATIONS

This application claims priority from U.S. Provisional Patent Application 62/184,696 filed Jun. 25, 2015, which is incorporated herein by reference.

### STATEMENT OF GOVERNMENT SPONSORED SUPPORT

This invention was made with Government support under contract NSF/AST1407353 awarded by the National Science Foundation. The Government has certain rights in the invention.

### FIELD OF THE INVENTION

The present invention relates generally to methods and devices for depositing material coatings. More specifically, it relates to techniques for deposition of high quality optical coatings on very large substrates.

### BACKGROUND OF THE INVENTION

Durable silver-based mirrors have long been a goal for astronomical telescopes. Silver is a relatively easy material to deposit and has excellent reflectivity and low emissivity in the visible and IR, but bare Ag quickly tarnishes (mostly due to oxidation with sulfur compounds) or forms salts with halides. To provide a long-lasting silver coating, the silver must be protected by barrier layers of transparent dielectrics in order to prevent tarnish and corrosion. These protective layers can also be used to provide an interference boost in the blue, where the reflectivity of Ag starts to fall. Unfortunately, Ag absorbs strongly near 320 nm and it is nearly impossible to get good reflectivity at λ<340 nm unless multiple high/low-index stacks are used, which in turn negatively impacts the reflectivity and low-emissivity elsewhere. Silver reflectivity can also be diminished in the blue by the phenomenon of surface plasmon resonances.

Existing efforts at protected-Ag mirror coatings includes a technique used in the Gemini telescopes, which employs two thin films over the Ag, one of Nickel Chromium Nitride (NiCrNx) and a second of Silicon Nitride (SiNx). The use of NiCrNx results in unacceptably poor reflectivity at blue and especially ultraviolet wavelengths (<400 nm). This coating and variants have been deposited using Physical Vapor Deposition (PVD), both by magnetron sputtering and e-beam ion-assisted deposition.

In the case of anti-reflection (AR) coatings on lenses, conventional coating designs often call for ˜10-20 different thin film layers to achieve the desired optical performance. There are significant difficulties in achieving uniform layer thickness over large substrates, particularly those with steeply curving surfaces, and controlling each layer thickness to high precision.

### SUMMARY OF THE INVENTION

In contrast to prior methods, the present invention uses a novel technique employing Atomic Layer Deposition (ALD), a sequential form of Chemical Vapor Deposition (CVD), for depositing barrier/protection layers over the silver of large optical components. In contrast with conventional ALD techniques, the present provides techniques that use ALD with the substrate as a reaction chamber wall, matches the shape of the opposite wall to the substrate shape, or has a small reaction chamber height in order to keep the volume small and therefore keep duty cycles short.

Conventional wisdom views ALD as not feasible to the coatings industry in general because it is inherently a slow process (only a few atomic layers per minute), whereas CVD and PVD can have the high deposition rates needed for mass production of parts. A typical ALD duty cycle is 10-20 s, so deposition rates of order 200A per hour are typical. This makes ALD impractical for most uses in the optical thin-film industry.

In addition, the ALD process is conventionally performed by placing a substrate in an enclosed reaction chamber. Very large astronomical mirrors, however, would require extremely large volume chambers using the conventional approach. Moreover, the deposition process would be inefficient and very slow, due to the long times it would take to evacuate and purge such reaction chamber twice during each duty cycle.

The inventors have developed a technique to overcome the above problems. In one aspect, the present invention provides a practical process for applying high-performance optical coatings to large scale optics using atomic-layer deposition (ALD). It also provides an atomic layer deposition reaction chamber design for optical coatings, using the optical substrate as one wall of the chamber and shaping the opposing wall in order to minimize the reaction chamber volume. The small reaction chamber volume means large substrates can be coated at deposition rates that are practical. Although the production times may be long compared to mass production of small optical elements, astronomical mirrors and lenses are typically “one-offs” that allows for longer production times. The ALD process using the unique reaction chamber design allows coating large surfaces uniformly and also significantly improves barrier/protection properties in these films as compared to PVD, which is prone to pinholes and to the growth of defects due to self-shadowing during deposition. PVD and other conventional coating techniques can have significant difficulties in achieving uniformity and precisely controlled layer thickness over large substrates. In contrast, the methods of the present invention assure uniformity by the conformal nature of the ALD deposition, and the thickness can be easily calibrated and controlled to within a few atomic layers, with very good repeatability.

The present invention provides a method for optically coating a substrate. A reaction chamber is formed by joining the substrate and a plate using a compliant seal, where the substrate forms one wall of the reaction chamber and the plate forms an opposite wall of the reaction chamber. Preferably, the reaction chamber may be formed using O-rings that directly contact the inside surface of the substrate and the inside surface of the plate. In some embodiments, the reaction chamber may be formed by mounting the substrate in a frame and joining the frame to the plate using the compliant seal. The frame may include multiple substrates. The substrate has an inside surface inside the reaction chamber and an outside surface outside the reaction chamber. The inside surface of the plate has a shape matching a shape of the inside surface of the substrate. Preferably, the inside surface of the substrate and the inside surface of the plate are spaced from each other by no more than 1 cm. Atomic layer deposition is used to deposit one or more optical thin film layers on the inside surface of the substrate to produce a coating on the inside surface of the substrate. The outside surface is not coated. The substrate is then released from the plate. The method may also include creating a rough vacuum in a secondary chamber distinct from the reaction vacuum chamber, where the outside surface of the substrate faces the secondary chamber, in order to reduce differential pressure on the substrate.

### BRIEF DESCRIPTION OF THE DRAWINGS

FIG. 1 is a schematic cross-sectional view of an apparatus for a technique to coat large substrates using ALD, according to an embodiment of the invention.

FIGS. 2A-D are graphs showing the gas velocity in chambers whose opposite walls have various different separations.

### DETAILED DESCRIPTION

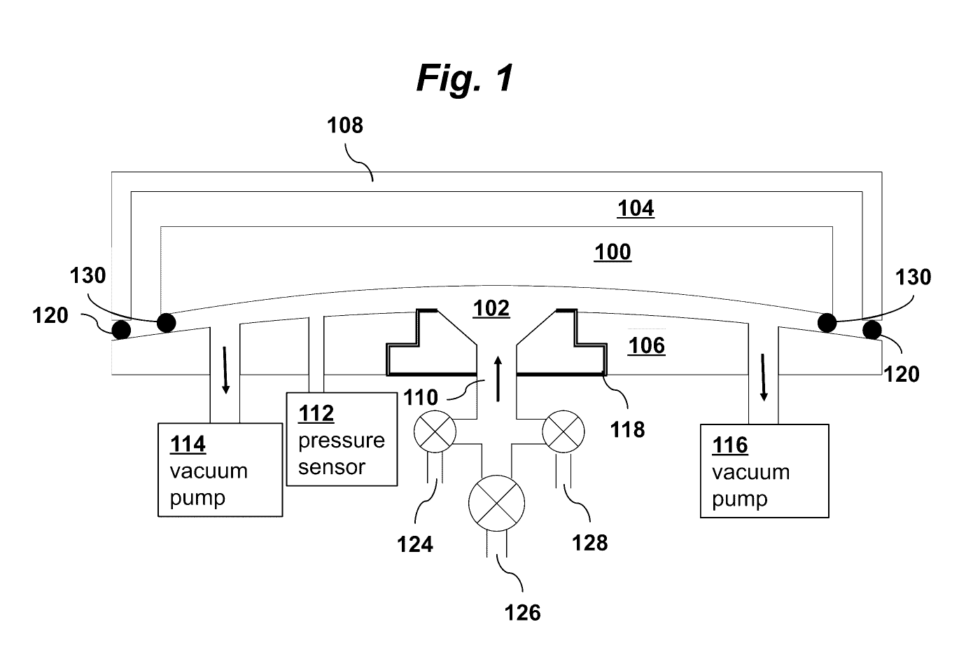

One embodiment of an apparatus for coating large substrates using ALD is shown in the schematic diagram of FIG. 1. A reaction chamber 102 is formed by joining a substrate 100 and a plate 106 using compliant seal 130.

The compliant seal is preferably an O-ring 130 that directly contacts an inside surface of the substrate 100 and an inside surface of the plate 106. The inside surface of the substrate 100 faces inside the reaction chamber 102 and an outside surface of the substrate faces outside the vacuum chamber 104. The outside surface typically includes a back surface and a side wall surface. The substrate thus forms one wall of the reaction chamber 102 and the plate 106 forms an opposite wall of the reaction chamber 102.

The inside surface of the plate 106 has a shape matching a shape of the inside surface of the substrate 100. In this context, matching shapes of the surfaces is defined to mean that the spacing between the surfaces is substantially uniform along their entire length (excluding the locations in the surface of the plate where openings for gas are positioned). Preferably, the inside surface of the substrate and the inside surface of the plate are spaced from each other by no more than 1 cm, so that the volume of the chamber 102 is small. Preferably, less than 20% of the reaction volume is due to the openings for gas in the plate. The substantially uniform spacing between the opposite surfaces of the reaction chamber is determined by the sizing of the compliant seal and/or any structure supporting the compliant seal.

In some embodiments, the reaction chamber 102 may be formed by mounting the substrate 100 in a frame and joining the frame to the plate 106 using the compliant seal 130. The substrate plus frame then plays the same role as the substrate in FIG. 1. In some embodiments, the frame may include multiple substrates. A frame in this context is defined as a vacuum-tight fixture that holds one or more substrates, and acts like a large single substrate.

In some embodiments, the apparatus preferably includes a secondary wall 108 joined to the plate 106 using compliant seal 120 (preferably an O-ring), forming a secondary chamber 104 distinct from the vacuum chamber 102. The outside surface of the substrate 100 faces the secondary chamber 104.

The plate has small openings to vacuum pumps 114, 116, pressure sensor 112, gas feed lines 124, 128, and gas purge line 126. Switching valves in these lines can be automatically operated by a process controller. Vacuum pumps 114, 116 are shown as separate pumps, but alternatively may be separate lines to a single large vacuum pump, which is preferred to provide a uniform vacuum all the way around to keep the flow uniform. Also, in practice, the vacuum pumps are alternately opened and closed, which is more easily accomplished by a single valve between the pump and several branching vacuum lines. A second rough or “dirty” vacuum in secondary chamber 104 prevents excessive stress on the optical substrate, and separates any mounting parts or actuators attached to the outer surfaces of the substrate that could contaminate the coating.

By using the substrate 100 as one wall of the reaction chamber 102, shaping the opposing wall of the plaste 106 to match the shape of the substrate 100, and using an O-ring or similar compliant seal to join these two parts, adequate vacuum can be achieved for the ALD process while keeping the volume of the effective reaction chamber 102 small. This means duty cycle times can be short enough to make the process practical for large substrates. The CVD nature of the ALD process means the coating uniformity can be achieved even with the large area-to-height aspect ratio, because the introduced vapors rapidly expand to fill the volume with constant pressure.

A large mirror in this context is defined to be a mirror with diameter at least 60 cm. The process may be used, for example, for mirrors with diameter 2 m, or even 10 m or more. It is also possible to coat an array of substrates using a frame or fixture of many small optics. For example, the techniques may be used to coat 10-40 cm diameter lenses (e.g., for cameras) with AR coatings, or to coat interference filters (of size 15 cm and larger). As noted, the benefit is uniformity for the lenses. For the filters, the present techniques are advantageous because it allows coating only one side, and also provides uniformity over large areas.

For some optics, a “dirty” vacuum in a secondary chamber 104 on the back/sides of the optical substrate 100 prevents damage to the substrate when the vacuum is created in the reaction chamber 102. The rough vacuum behind the substrate is useful to reduce mechanical strain on mirror, but it is not required.

According to one embodiment of a method for optically coating a substrate with the apparatus of FIG. 1, atomic layer deposition is used to deposit one or more optical thin film layers on the inside surface of the substrate 100 to produce a coating on the inside surface of the substrate. The substrate is then released from the plate 106 by relieving the vacuum.

In the embodiment of FIG. 1, the plate 106 is composite and most of it is custom built to match the shape of a specific substrate. In this case, there is a vacuum-sealed interface, 118, where the two parts of the plates detach. This means that the gas delivery system can be mated to a variety of custom plates, while only the vacuum lines must be custom attached to the custom portion of the plate. In another embodiment, a large flat plate can have a custom-made “filler” shape to take up most of the volume, and the filler shape provides the effective matching surface to form the reaction chamber wall. The filler shape may be fabricated out of any non-reactive vacuum compatible material, including but not limited to stainless steel or aluminum.

Atomic Layer Deposition (ALD) is a Chemical Vapor Deposition (CVD) technique that has gone from relatively new to industry standard in the semiconductor industry during the last decade or so. ALD is essentially a binary CVD process employing sequential self-limiting monolayers. By introducing the two reagents or “precursors” into the chamber sequentially, all reactions take place at the surface in a monolayer. This results in superb thickness control and uniformity.

The ALD process begins by creating a vacuum in the chamber 102 using vacuum pumps 114, 116. Pressure is sensed with sensor 112 connected to an automatic process controller. A first precursor chemical 124 is introduced through opening 110 into the vacuum reaction chamber 102. This first precursor 124 is typically an organo-metal such as tri-methyl aluminum, chosen because it forms a mono-layer on surfaces since it does not stick to itself. The reaction chamber 102 is then purged with an inert purge gas 126 through opening 110 and evacuated, leaving behind just the mono-layer of the precursor. A second reagent 128 (such as water vapor) is then introduced, reacting with the first precursor (now deposited on the inside surface of substrate 100) to produce the desired product, with byproducts left in a vapor form. The reaction chamber 102 is again purged and evacuated, removing the byproducts and the second reagent 128, and leaving one molecular layer of the desired material deposited on the inside surface of substrate 100. This binary process is repeated until the desired film thickness is achieved. Each duty cycle takes about 10-20 seconds, so deposition rates are low. The duty cycle is dominated by the time it takes to purge and evacuate the chamber adequately, so the larger the reaction chamber volume, the longer the duty cycle.

An overview of the process steps is as follows:
1. Introduce the first precursor (with an inert “carrier” gas). Ideally, the reagent forms a monolayer on surfaces in the chamber, including the substrate;
2. Purge and evacuate the chamber, leaving just the monolayer of the precursor;
3. Introduce the second reagent (often as a plasma); it reacts with the precursor monolayer to form the final product at the surface, and a volatile by-product; and
4. Purge and evacuate the chamber, leaving a monolayer of the desired material on the substrate.

The process control includes the correct sequencing and timing for opening and closing microvalves, so it is usually fully automated under computer control and does not require close monitoring.

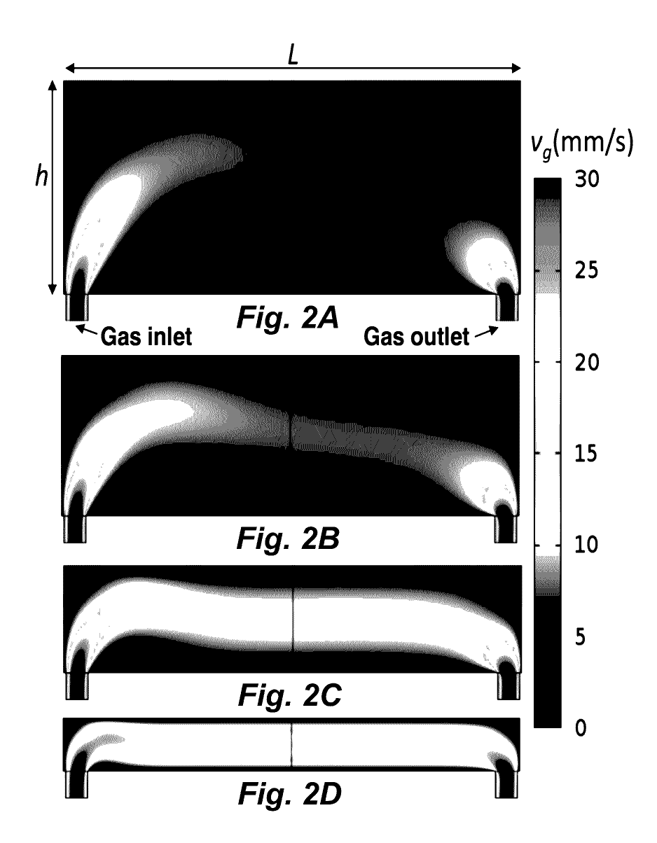

During the process preferably a continuous laminar flow is maintained to ensure uniformity in the deposition process. The small separation between substrate and plate helps keep flow laminar. As illustrated in the gas velocity maps of FIGS. 2A-D, the flow of gas has the best laminar flow in chambers whose opposite walls have a separation of 1 cm or less. The chambers in this example have a length of L=100 mm and various chamber heights. In FIG. 2A, h=40 mm. In FIG. 2B, h=30 mm. In FIG. 2C, h=20 mm. In FIG. 2D, h=10 mm. The inlet gas flow rate (F) and the outlet gas pressure are fixed to 20 sccm and 1.0×10⁴ Pa. The gas flow exhibits a uniform laminar flow when h=10 mm, thus the upper bound of h for L=100 mm under these specific gas inlet and outlet conditions seems to be approximately 10 mm. Nearly identical results are found in simulations with curved chamber walls with uniform spacing. For longer chambers, laminar flow may be obtained for wider spaced walls.

In one illustrative example of an ALD process according to the invention, a durable coatings of just ALD-Al₂O₃ is deposited as a barrier layer over Ag. Al₂O₃ is a material that is very easy to deposit with ALD, so the process parameters are relatively forgiving. To avoid condensation, water is preferably added after pre-warming the samples.

For metal oxides, prevalent oxygen precursors include: H₂O, O₂, N₂O, and O₃ mixed with other gases (e.g., N₂) cracked with or without plasma. In addition, a range of metal precursors with appropriate vapor pressure are commercially available. Conventionally, plasma used in ALD is cold (i.e., gas temperature is much lower than electron temperature). Plasma is ignited and sustained by supplying AC power (e.g., RF 13.56 Hz and microwave 2.45 GHz). Typical substrate temperatures range from room temperature to 600 C, depending on detailed chemical characteristics of a specific metal precursor and whether plasma is used or not. ALD cycle time that needs to be optimized depending on substrate temperature ranges from 2-30 s.

Two types of nitrides that may be used with plasma enhanced ALD are AlN and TiN. For example, process parameters for such ALD are discussed in Choi et al., “Nitride memristors,” Appl Phys A (2012) 109:1-4. Si₃N₄ may also be deposited by ALD.

The fact the ALD is a vapor process means the aspect ratio of the chamber can be very high, as the gases will rapidly diffuse throughout the volume. Furthermore, the vacuum requirements are fairly easy to meet: ˜1 mTorr base pressure; such vacuums can easily be met with an O-ring seal. Key features of embodiments of the present invention include one or more of the following: 1) the substrate forms one wall of the reaction chamber, with the ALD process taking place only on one side of the substrate (the inner surface), 2) the substrate, which forms a wall of the reaction chamber, is removable after the ALD process, 3) the reaction chamber has a small volume, allowing practical duty cycle times, achieved by a uniform and small separation between surface of the inner substrate and the surface of the plate which forms the chamber wall opposite to the substrate, and 4) a compliant vacuum seal between the substrate and the plate.

One advantage of this coating technique is that only one side of the substrate is exposed to the ALD process. For example, if films, sensors, or other features are present on the other side, the coating process does not interfere with them. Also a lens may require coatings of different thickness on different sides to tune to different curvatures. The substrate can be flipped over and the process repeated to coat its other side, e.g., for a large lens. A different coating may be applied on the opposite side, which is not possible in conventional ALD methods.

The advantages of ALD include conformal and smooth films, usually amorphous microstructure, and superb uniformity and thickness control. It does not require very high vacuum or temperature, and it can produce most common oxides and nitrides.

The present invention has applications beyond telescope mirrors. Interference filters and dichroics and all-dielectric mirrors require excellent uniformity and thickness control and are needed in increasingly-large sizes. ALD would be viable for these products for the same reasons as for AR coatings. The invention would make coating such large optics practical.

This apparatus can be used to deposit any material that can be produced with ALD, including optically-useful oxides, nitrides and fluorides.

1. A method for optically coating a substrate, the method comprising:
forming a reaction chamber by joining the substrate and a plate using a compliant seal, wherein the substrate forms one wall of the reaction chamber and the plate forms an opposite wall of the reaction chamber, wherein the substrate has an inside surface inside the reaction chamber and an outside surface outside the reaction chamber, wherein an inside surface of the plate has a shape matching a shape of the inside surface of the substrate;
using atomic layer deposition to deposit one or more optical thin film layers on the inside surface of the substrate to produce a coating on the inside surface of the substrate; and
releasing the substrate from the plate.

2. The method of claim 1 wherein the inside surface of the substrate and the inside surface of the plate are uniformly spaced from each other with a separation no more than 1 cm.

3. The method of claim 1 further comprising creating a rough vacuum in a secondary chamber distinct from the vacuum chamber, where the outside surface of the substrate faces the secondary chamber.

4. The method of claim 1 wherein forming a reaction chamber by joining the substrate and the plate comprises using O-rings that directly contact the inside surface of the substrate and the inside surface of the plate.

5. The method of claim 1 wherein forming a reaction chamber by joining the substrate and the plate comprises mounting the substrate in a frame and joining the frame to the plate using the compliant seal.

6. The method of claim 5 wherein the frame comprises multiple substrates.
